(19) United States
(12) Patent Application Publication
(10) Pub. No.: US 2009/0001366 A1
(43) Pub. Date: Jan. 1, 2009

(54) Wafer Arrangement and Method for Manufacturing a Wafer Arrangement

(76) Inventors: Stephan Dobritz, Dresden (DE); Stefan Ruckmich, Dresden (DE)

Correspondence Address: SLATER & MATSIL, L.L.P., 17950 PRESTON ROAD, SUITE 1000, DALLAS, TX, 75252, US

(21) Appl. No.: 11/778,555

(22) Filed: Jul. 16, 2007

(30) Foreign Application Priority Data
Jun. 29, 2007 (DE) 10 2007 030 286.1

(51) Int. Cl. H01L 23/58; G01R 31/26; H01L 21/66

(52) U.S. Cl. 257/48; 324/763; 438/18; 257/E23.01; 257/E21.521

(57) ABSTRACT

A wafer arrangement in accordance with an embodiment of the invention includes a wafer having a plurality of dice, wherein at least some of the dice have a first connection, and at least one contact pad formed at the wafer edge, wherein a plurality of first connections are coupled by means of a section of a redistribution layer and the contact pad is formed by the section of the redistribution layer.

This application claims priority to German Patent Application 10 2007 030 286.1, which was filed Jun. 29, 2007, and is incorporated herein by reference.

### TECHNICAL FIELD

Embodiments of the present invention relate generally to a wafer arrangement and a method for manufacturing a wafer arrangement.

### BACKGROUND

Wafer level packaging technologies make it possible to carry out all the process steps of IC packaging at the wafer level. The packaging of the whole wafer permits a high degree of process integration. One prerequisite for this is, for example, that the size of the package be identical to the size of the chip or die. A further prerequisite, therefore, is that the connections be situated within the chip edges or die edges. In wafer level packages an additional wiring level is added, for example, which effects redistribution wiring of the bonding pads onto the chip or die surface. In this case, the redistribution wiring is currently effected, for example, by the arrangement of a redistribution level, also referred to as a redistribution layer (RDL). The manufacturing of a redistribution layer may essentially include the following steps, for example: sputtering a seed layer, applying a photoresist, photolithographically patterning the latter and forming a trench structure, depositing (for example, by electrodeposition) a metal layer stack and removing the photoresist and the seed layer arranged outside the trench structure. The redistribution level may subsequently be provided with a dielectric layer which can be photolithographically patterned in order to form connections (bonding pads).

Once the dice have been completed at the wafer level, the dice can be singulated by sawing the wafers, for example, along singulation regions, which can also be referred to as sawing routes.

In order to ascertain, however, whether the dice meet the required quality demands, the dice are usually tested at an elevated operating voltage and high temperature in a so-called burn-in method, such that those dice which have weak points in respect of reliability are caused to fail as early as possible during the burn-in. In this case, the dice are tested during and after the burn-in and poor components are identified and separated out. Bum-in treatments of dice have conventionally been carried out at the die level and not at the wafer level.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic illustration of a wafer with a plurality of dice;

FIG. 2 shows a schematic illustration of a section of a wafer in accordance with FIG. 1 with a plurality of contact pads at the wafer edge;

FIG. 3 shows a schematic illustration of a wafer section with a redistribution layer connecting the second connections of the dice, in accordance with one exemplary embodiment of the invention; and

FIG. 4 shows a schematic illustration of a wafer section with a redistribution layer connecting the second connections of the dice, in accordance with another exemplary embodiment of the invention.

### DETAILED DESCRIPTION OF ILLUSTRATIVE EMBODIMENTS

In an embodiment of the invention, a completely processed wafer as a whole is provided, for example, to a burn-in and test process before the wafer is singulated into individual dice and the dice are encapsulated in a plastic housing, for example.

In an embodiment of the invention, provision is made for a wafer arrangement and a method for manufacturing a wafer arrangement by means of which, for example, the carrying out of a burn-in and test process at the wafer level can be reliably effected.

In accordance with one embodiment of the invention, a wafer arrangement includes a wafer having a plurality of dice, wherein at least some of the dice have a first connection, and a contact pad formed at the wafer edge, wherein the first connections of at least some of the dice are coupled by means of a section of a redistribution layer and the contact pad is formed by the section of the redistribution layer.

In accordance with one embodiment of the invention, each of the first connections is assigned a second connection arranged on a section of a redistribution layer.

In accordance with another embodiment of the invention, a method for manufacturing a wafer arrangement includes forming a plurality of dice in a wafer, such that at least some of the dice have a first connection, forming a redistribution layer in such a way that the first connections of at least some of the dice are coupled to one another and a section of the redistribution layer is arranged on an edge region of the wafer, which can be used as contact pad.

In accordance with one embodiment of the method, each of the first connections of the dice is assigned a second connection formed by a section of a redistribution layer, and wherein the second connections are coupled to one another.

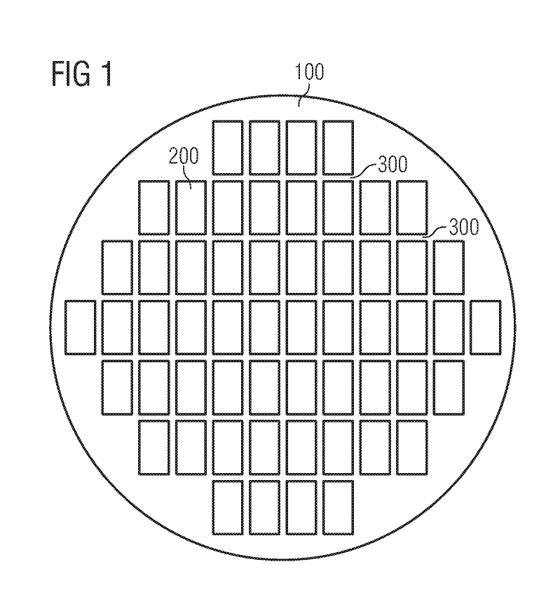

As can be seen from FIG. 1, a plurality of dice 200 are arranged in rows on a wafer 100. Singulation regions 300 running vertically and horizontally in the illustration in each case are provided between the individual dice 200, among which singulation regions the dice 200 can be singulated after they have been completed at the wafer level.

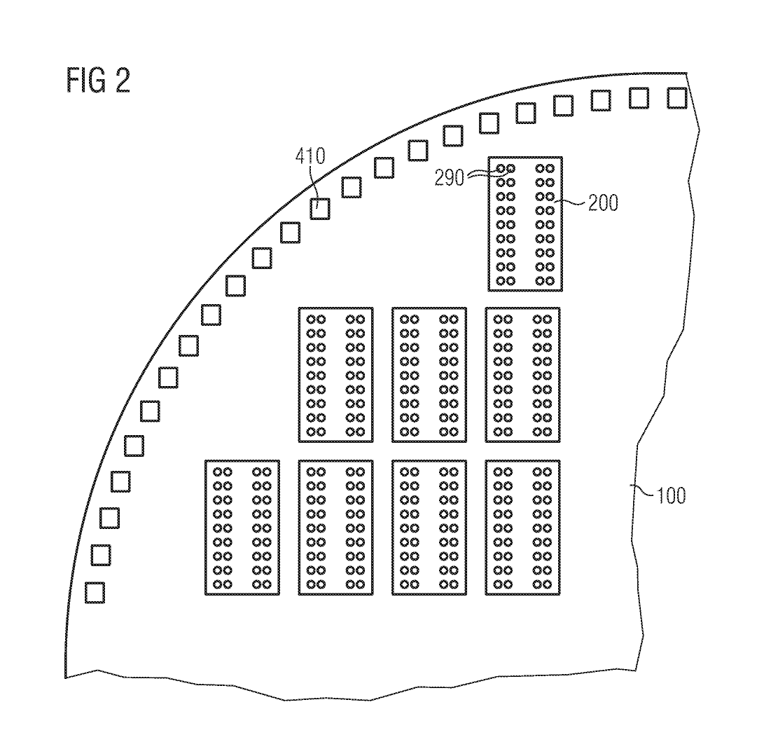

As can be seen from FIG. 2, the dice 200 in accordance with one embodiment have, for example, in each case a plurality of second connections 290 arranged, for example, in the edge region of a respective die 200. The second connections 290 are formed, for example, by means of a respective section of a redistribution layer, which extends from first connections (not illustrated) provided, for example, in the center of the dice 200. A plurality of contact pads 410 are arranged at the outer circumferential edge of the wafer 100, in that outer region in which usually no dice are formed, the function and configuration of which contact pads will be explained in more detail with reference to one of the subsequent figures. Although FIG. 2 illustrates only an excerpt from a wafer 100, the contact pads 410 can be arranged in a manner distributed on the entire outer circumferential region of the wafer 100.

In accordance with another exemplary embodiment, however, the second connections 290 illustrated can also be first connections formed directly in or on the die or chip, such that they can be connections that have not been subjected to redistribution wiring on the dice.

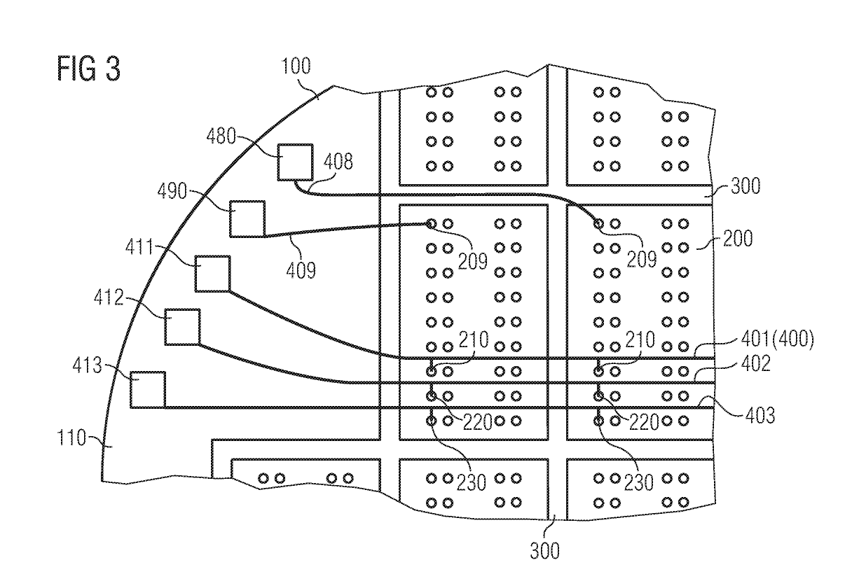

An embodiment of a wafer arrangement which is suitable for a burn-in treatment and test, for example, is explained in more detail with reference to the schematic illustration in accordance with FIG. 3, wherein the wafer arrangement includes a wafer 100 having a plurality of dice 200 (only two dice are illustrated), wherein at least some of the dice 200 have: a first connection (not illustrated) and a second connection 210, wherein the second connection 210 is formed by a section 401 of a redistribution layer 400 which is coupled to the first connection, and at least one contact pad arranged at the wafer edge 110, wherein the second connections 210 of at least some of the dice 200 in accordance with this embodiment are coupled by means of sections 401 of the same redistribution layer 400 and the contact pad 411 is formed by a section of the redistribution layer 400. That section 401 of the redistribution layer 400 by means of which, on the one hand, the first connection is coupled to the second connection 210 and which, on the other hand, connects the second connections 210 of the respective dice 200 is, for example, also referred to as an interconnect connect or trace.

In accordance with a further exemplary embodiment of the invention, the plurality of dice 200 in each case has a plurality of first connections (not illustrated) and a plurality of second connections 210, 220, 230, wherein at least some of the respectively mutually corresponding second connections 210 or 220 or 230 of at least some of the dice 200 are in each case coupled by means of a section (or interconnect) 401 or 402 or 403 of the same redistribution layer 400 by which a contact pad 411 or 412 or 413 is respectively formed.

The dice 200 processed on the wafer 100 are, for example, in each case formed identically and have respectively mutually corresponding first connections. Using a redistribution layer, the first connections, which may be situated, for example, in the center of a die, are subjected to redistribution wiring into an edge region of the respective die 200, the associated second connection 210, 220, 230 being formed or provided by a respective section 401, 402, 403 of the redistribution layer 400.

As can be seen from FIG. 3, in one exemplary embodiment of the invention, by way of example, the redistribution layer 400 can be arranged, by means of a suitable trench structure applied beforehand, on the wafer 100 in such a way that sections 401 of the redistribution layer 400 extend over a specific number of dice 200 toward the wafer edge 110, wherein sections which form the redistribution wiring from a specific first connection to the assigned second connection 210 branch off from the section 401 of the redistribution layer 400. Such a branching-off section configured as redistribution wiring is arranged at each of those dice 200 whose corresponding second connection 210 is intended to be coupled to the section 401 of the redistribution layer 400. In this way, the respectively mutually corresponding second connections 210 of all or a portion of the dice 200 arranged alongside one another, for example, in a row can be coupled to one another by applying the one redistribution layer 400. In this case, the wafer arrangement can be formed in such a way that the mutually corresponding second connections 210 are connected up in parallel by means of the redistribution layer 400. As already explained and illustrated in FIG. 3, the section 401 of the redistribution layer 400 extends as far as the wafer edge 110, wherein there at the wafer edge 110 the contact pad 411 is formed by a section of the redistribution layer 400.

This means that the wafer arrangement in accordance with one exemplary embodiment of the invention can be produced using a redistribution layer by effecting the redistribution wiring of the corresponding first connections to the position provided for the assigned second connections, to be precise by means of a respective section of the redistribution layer, wherein the aforementioned sections by which the second connections are formed do not end at the position provided for the second connections, but rather are formed integrally with that section of the redistribution layer 400 which extends across all or a portion of the dice 200 arranged alongside one another in a row and is formed as far as toward the wafer edge 110. Consequently, the interconnect sections serving for redistribution wiring and the interconnect sections used for coupling the corresponding second connections to one another are produced by means of this one redistribution layer.

In other words, using only one redistribution layer, for example, it is possible to produce all of the desired or required sections/interconnects of the wafer arrangement in accordance with one exemplary embodiment on the wafer by virtue of mutually corresponding second connections 220 of all or a portion of the dice 200 arranged alongside one another in a row being coupled to one another by means of a further interconnect 402, further mutually corresponding second connections 203 of all or a portion of the dice 200 arranged alongside one another in a row being coupled to one another by means of yet another interconnect 403, and so on, wherein each of the interconnects 401, 402, 403 of the redistribution layer 400 extends as far as the wafer edge, such that the corresponding contact pad 411, 412, 413 is provided by a section arranged in each case at the wafer edge 110.

In this embodiment it may be provided that the sections/interconnects at the redistribution layer 400 which extend on the surface of the dice 200 are arranged on so-called free areas of the dice 200, wherein free areas should be understood to mean those area sections on the top side of the dice 200 at which no connections are provided.

Consequently, the wafer arrangement can be formed in such a way that a plurality of interconnects of the same redistribution layer are arranged, by which a predetermined number of respectively mutually corresponding second connections of a predetermined number of dice 200 are in each case coupled to one another, wherein each of the interconnects is formed as far as the wafer edge 110, in the region of which the section serving as a contact pad is arranged.

As can furthermore be seen from FIG. 3, in the wafer arrangement in accordance with one exemplary embodiment, at least one further second connection 209 of each of the plurality of dice 200 can be coupled to a separate interconnect 409 or 408 of the same redistribution layer 400, which respectively forms a contact pad 490 or 480 in the region of the wafer edge 110. As in the case of the second connections described above, the second connection 209 under discussion is formed by a section 409 (408) of the redistribution layer 400 which extends from the correspondingly associated first connection (not illustrated), wherein the section 409 (408) of the redistribution layer 400 does not end in the position predetermined for the second connection 209 on the die 200, but rather is formed as far as toward the wafer edge 110.

In accordance with the embodiment of a wafer arrangement that is illustrated in FIG. 3, a specific, technically expedient number of mutually corresponding second connections 210, 220, 230 . . . for example, of all the dice 200 arranged in a row can consequently be coupled by means of a respective section/interconnect 401, 402, 403 . . . of the same redistribution layer 400, which are formed as far as toward the wafer edge 110 for the purpose of providing contact pads 411, 412, 413 . . . at an expedient position at the wafer edge. The contact pads 411, 412, 413 of, for example, three such sections 401, 402, 403 of the redistribution layer 400 can be arranged at the left-hand edge of the wafer in the illustration and, for example, three further contact pads of three further sections/interconnects of the same redistribution layer can be arranged, for example, at the right-hand edge of the wafer (not illustrated). Furthermore, in each case at least one further second connection 209 of each of the dice 200 is coupled to a separate section/separate interconnect 490, 480 of the redistribution layer 400, which is led as far as the wafer edge, so that a section of the separate interconnect 409, 408 can be used as a contact pad 490, 480. The arrangement of the further second connection 209 from which the section or the interconnect 409 or 408 runs to the edge region of the wafer is effected from the assigned first connection in the form of a redistribution wiring by means of precisely the section 409 or 408.

In contrast to the embodiment described previously, the second connections 210, 220, 230 and 209 formed on the die 200 can also be connections which are formed directly on the die and which have not been subjected to redistribution wiring. In this case, the respectively mutually corresponding second connections 210, 220, 230 of the dies 200, in the same way as described previously, are in each case coupled to one another by means of an interconnect 401, 402, 403, and the chip select connection 209 is coupled to the interconnect 409, wherein the interconnects 401, 402, 403, 409 are sections or parts (also called traces) of the same redistribution layer.

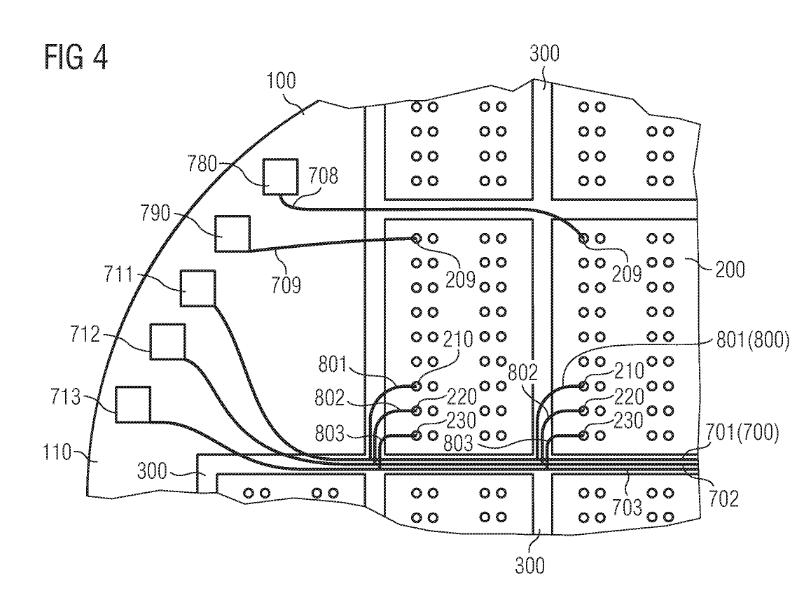

A further embodiment of the wafer arrangement according to the invention is described with reference to FIG. 4.

FIG. 4 shows a schematic illustration of a wafer section of a wafer 100, in which second connections of a plurality of dice 200 are coupled by manufacturing two redistribution layers 700 and 800.

As can be seen, the plurality of the dice 200 formed essentially in identical fashion has in each case a plurality of second connections 210, 220, 230 . . . . The second connections 210, 220, 230 . . . are in each case formed by a section 801, 802, 803 . . . of a redistribution layer 800 which serves for redistribution wiring and which is in each case coupled to an assigned first connection (not illustrated). The sections/interconnects 801, 802, 803 of the redistribution layer 800 in each case extend, proceeding from the corresponding first connection, across the position at which the assigned second connection 210, 220, 230 . . . is provided, as far as, for example, into a singulation region 300 adjoining the corresponding die 200.

By means of a respective interconnect or section 701, 702, 703 . . . of a further redistribution layer 700, the respectively mutually corresponding second connections 210, 220, 230 . . . , that is to say the ends, projecting into the singulation regions 300, of the sections/interconnects 801, 802, 803 . . . of the redistribution layer 800 of some or of all of the dice 200 arranged alongside one another in a row are coupled to one another, the sections 701, 702, 703 . . . of the redistribution layer 700 being embodied as far as the wafer edge 110. As in the exemplary embodiment described previously, a corresponding contact pad 711, 712, 713 . . . is formed by a respective section 701, 702, 703 . . . of the redistribution layer 700 at the wafer edge 110, the contact pad being set up as contact-connecting connection for a contact-connecting apparatus (not illustrated) of a burn-in/test device. The connection of the sections 801, 802, 803 . . . of the redistribution layer 800 which have the second connections 210, 220, 230 . . . to the respectively assigned sections 701, 702, 703 . . . of the redistribution layer 700 can be configured in such a way that the second connections 210, 220, 230 . . . of the individual dice 200 are connected up in parallel.

The production of the wafer arrangement in accordance with the exemplary embodiment illustrated in FIG. 4 can be effected, for example, in such a way that by applying firstly the redistribution layer 700, the interconnects (or sections or interconnect sections or traces) 701, 702, 703 . . . illustrated in FIG. 4 are arranged on the wafer 100. In the region on the wafer 100 in which the dice 200 are arranged, it is possible to form the interconnects 701, 702, 703 . . . for example in or along singulation regions 300 between the wafers, also called sawing routes, wherein the interconnects 701, 702, 703 . . . can extend, for example, across virtually the entire wafer 100 and provide the respective section for the contact pad 711, 712, 713 . . . in the region of the wafer edge.

By applying a further redistribution layer 800 of a subsequent method step sequence, the interconnects 801, 802, 803, . . . can then be arranged in such a way that the respective interconnect 801, 802, 803, . . . extends from the first connection beyond the position for the assigned second connection 210, 220, 230, . . . as far as the connection region (connection node points) provided therefor at the respective one of the assigned interconnects 701, 702, 703 . . . of the redistribution layer 700.

It is also possible, however, for a respective interconnect serving for the redistribution wiring to be effected from a first connection toward the position of the respectively assigned second connection 210, 220, 230, . . . as early as during the processing of the (first) redistribution layer 700, such that those interconnects 801, 802, 803 . . . by means of which the connections 210, 220, 230, . . . are coupled to the respectively assigned interconnect 701, 702, 703 . . . are arranged by means of the subsequently applied redistribution layer 800.

Likewise, it is also possible in accordance with a further exemplary embodiment that the second connections 210, 220, 230, . . . are not connections subjected to redistribution wiring but rather first connections (direct connections) which are formed directly in or on the dice 200 and from which the section or the interconnects 801, 802, 803, . . . of the redistribution layer 800 in each case extends as far as toward the respectively assigned interconnect 701, 702, 703, . . . of the redistribution layer 700, in which case the further second connection 209, then formed as a direct connection, of each of the dice 200 can be coupled, for example, to a section of the redistribution layer 700 or of the redistribution layer 800 which extends as far as the wafer edge.

As can be seen from FIG. 4, the arrangement of the interconnects 801, 802, 803, . . . of the redistribution layer 800 can be effected for example in such a way that substantial sections thereof run in the adjoining singulation regions 300.

In the case of the wafer arrangement in accordance with the exemplary embodiment illustrated in FIG. 4, for example, at least one further second connection 209 of each of the plurality of dice 200 (only two dice are illustrated) is coupled to a separate interconnect 709 or 708 of one of the redistribution layers 700 or 800, a contact pad 790 or 780 being formed by the separate interconnect 709 or 708 in the region of the wafer edge 110. The interconnect 709 or 708 of one of the redistribution layers 700 or 800 by which the further second connection 209 is formed extends from the correspondingly associated first connection (not illustrated) and runs without interruption toward the wafer edge 110. That is to say that the interconnect 709 or 708 does not end in the position predetermined for the further second connection 209 on the die 200, but rather can be embodied integrally as far as toward the wafer edge 110. Although FIG. 4 illustrates only one further second connection 209 on a die 200, which is formed by a separate interconnect section 709 or 708 of a redistribution layer 700 or 800, a plurality, that is to say a technically expedient number of further second connections 209 of each individual die 200 can in each case be coupled by means of an interconnect section of a redistribution layer by which a contact pad is provided in each case.

By means of the wafer arrangement in accordance with one of the exemplary embodiments described, the connection lines required for feeding, for example, signals, for example, electrical voltages, etc. to the corresponding connections of the dice can consequently be significantly reduced, whereby the number of required contact pads is consequently reduced as well. On account of the reduced number of contact pads at the wafer edge, the contact pads themselves can be made larger. This has the effect that the connections of a contact-connecting apparatus, for example, of a burn-in and test method contact-connecting apparatus, which make contact with the contact pads can be formed in a correspondingly larger and less complicated fashion. Since a smaller number of contact pads on the wafer have to be contacted-connected for carrying out the burn-in and test process, the contact forces that necessarily have to be applied to the wafer edge by the contact-connecting apparatus are likewise reduced.

The wafer arrangement in accordance with one of the exemplary embodiments can be used, for example, for a burn-in method and testing burn-in method at the wafer level. One possible burn-in and test method for the dice formed in the wafer is effected in a manner that is conventional at the present time, that is to say with conventional parameters (application of signals, voltage or the like to predetermined connections of the dice with predetermined temperature and duration and also testing/read-out of specific data output signals), such that the burn-in and test method itself will not be discussed in any greater detail at this juncture.

By means of a correspondingly adapted burn-in and test method contact-connecting apparatus (not illustrated), the connections of which can in each case be brought into electrically conductive contact with one of the contact pads, it is possible, for example, proceeding from the contact pads 411, 412, 413 . . . or 711, 712, 713 . . . via the interconnects 401, 402, 403 . . . or 701, 702, 703 . . . and 801, 802, 803 . . . connected thereto, to feed or apply addresses, signals, voltage, ground or the like to the second connections 210, 220, 230 . . . of all the second connections of the dice 200 that are connected to one of the respective interconnects 401, 402, 403 . . . or 701, 702, 703 . . . and 801, 802, 803 . . . .

Furthermore, the at least one further second connection 209 which is coupled to an interconnect 709 (708) of the redistribution layer 700 or the redistribution layer 800 can be a chip select connection.

Consequently, with the wafer arrangement in accordance with one exemplary embodiment of the invention it is possible to carry out a so-called full wafer test, in which all the dice of a wafer can be tested simultaneously (multi-die test or parallel test), the parallelization being effected by means of the interconnects of a redistribution layer.

Although examples of the wafer arrangements in which at least one portion of the respectively mutually corresponding second connections of all the dice 200 arranged in a row are in each case coupled by means of a section/interconnect of at least one redistribution layer have been described with reference to FIG. 3 and FIG. 4, it is also possible to subdivide the dice arranged in the wafer into so-called clusters and to couple together at least one portion of the respectively mutually corresponding second connections of all the dice associated with a cluster or of all the dice arranged in a row within a cluster.

Although not illustrated, one exemplary embodiment of the invention provides an apparatus for carrying out a burn-in and test process of dice in a wafer with a wafer arrangement in accordance with one of the exemplary embodiments mentioned, including a contact-connecting apparatus having contact connections which are formed for making electrical contact with contact pads on the wafer, wherein all dice coupled to the contact-connected contact pads can be simultaneously subjected to a predefinable burn-in and test process by means of the contact-connecting apparatus. In accordance with one exemplary embodiment, the contact-connecting apparatus can be part of a burn-in device.

A further exemplary embodiment of the invention provides a method for the burn-in and test process of dice on a wafer with a wafer arrangement in accordance with one of the exemplary embodiments mentioned, including contact-connecting the contact pads arranged on the wafer by means of a contact-connecting apparatus in a burn-in and test device, loading/stressing all the dice coupled to the contact pads with/under predetermined burn-in parameters, and testing the dice at defined time intervals during and after the burn-in treatment.

As already mentioned elsewhere, by means of the contact-connecting apparatus (if desired) all the dice arranged in the wafer, at the wafer level, can be subjected to a burn-in and test process that is customary, per se, by virtue of the contact connections of the contact-connecting apparatus making contact with the contact pads coupled to the corresponding dice. A burn-in and test process is made possible since the dice of the wafer arrangement arranged on the wafer are connected up in a manner suitable for a burn-in and test process.

After the burn-in and test process has been concluded, it is possible to singulate the dice in the wafer. This singulation (or dicing) can be effected, for example, by means of sawing or laser cutting or laser fusing (alternatively, also by means of etching or mechanical breaking), wherein, as is also conventional, the dice 200 are released from the wafer level along the singulation regions.

Since, in the case of the wafer arrangement in accordance with one exemplary embodiment, that section of a redistribution layer which couples the first or the second connections to one another and has the contact pad and also the separate section of the redistribution layer, for example, the at least one further second connection is formed and which is subjected to redistribution wiring toward the wafer edge, are in each case arranged at least section by section in or along the singulation regions, these sections of the redistribution layers which are arranged in the singulation regions are concomitantly removed at the same time during singulation, such that no separate complicated removal is necessary for the removal of the redistribution layers serving as supply lines. The sections of the redistribution layers which are still situated on the free areas of the dice even after a singulation can be removed by means of an etching process, for example. This can be done, for example, depending on what type of dice they are and the purpose for which the dice are intended to be used, or whether or not the sections of the redistribution layer that have remained on the free areas could influence the later function of the die. Those sections of the redistribution layer by means of which the redistribution wiring from the respective first connections to the associated second connections is effected and which are arranged in the position provided for the second connections can furthermore be used for the arrangement and fixing of solder balls or other suitable contact elements.

The dice which are formed in the wafer having the wafer arrangement may be memory chips or logic chips, for example.

Furthermore, it is possible that the contact pads at the wafer edge which are formed by a section of the redistribution layer and the dimensions of which, on account of the space sufficiently available at the wafer edge, can be made considerably larger relative to the width of the respective interconnect itself can, if appropriate, in each case be equipped with a pad contact-connection element.

To summarize, it can be established that the wafer arrangement in accordance with one exemplary embodiment of the invention provides a suitable arrangement on a wafer which can be used to carry out a burn-in and test method at the wafer level in which all the dice formed in the wafer can be jointly subjected to a burn-in and test process since the dice of the wafer arrangement arranged on the wafer are connected up in a manner suitable for a burn-in and test process. By virtue of the coupling of at least one portion of the mutually corresponding second (or first) connections of, for example, all the dice arranged alongside one another in a row by means of a respective interconnect which is formed by a redistribution layer and sections of which are utilized, for example, for the redistribution wiring of the first to the second connections, it is possible to significantly reduce the number of supply lines required for feeding signals, addresses, etc. and of supply lines required for testing data output signals on the wafer. Since, in the case of the wafer arrangement, in accordance with one embodiment of the invention, the production of the interconnects which implement the redistribution wiring of first to assigned second connections and the coupling of mutually corresponding second connections of a plurality of dice with arrangement of contact pads at the wafer edge can furthermore be effected by means of one redistribution layer or by means of two redistribution layers, the costs for manufacturing a wafer arrangement suitable for a burn-in and test method at the wafer level can be significantly reduced.

Since, for example, substantial sections (interconnects) of the respective redistribution layer are arranged in or along singulation regions between the dice, at least the sections can be removed without an additional method step during the singulation of the dice. If necessary, the sections of the redistribution layer which have possibly remained on the dice can be removed by means of a selective etching process. This means that the electrical properties of the dice are not impaired during the production of the wafer arrangement and during the removal thereof.

Furthermore, in the case of the wafer arrangement in accordance with one exemplary embodiment, it is not necessary to arrange at the wafer edge separate contact connections in the form of contact pins, for example, which can be contact-connected by corresponding contacts of a contact-connecting apparatus since, in the case of the wafer arrangement, the contact pads are formed by sections of the redistribution layer.

Owing to the reduction of the number of corresponding sections/interconnects (supply lines) which are formed by the one redistribution layer (FIG. 3) or by the two redistribution layers (FIG. 4) and which extend right into the edge region of the wafer, the basic area of the respective contact pad can be made correspondingly larger. The consequence of this is that the technical realization of the contact-connection elements of the, for example, burn-in and test contact-connecting apparatus can be effected more simply and hence also more cost-effectively.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A wafer arrangement, comprising:
a wafer having:
a plurality of dice, wherein at least some of the dice have a first connection; and
a contact pad formed at an edge of the wafer;
wherein a plurality of first connections are coupled by means of a section of a redistribution layer and the contact pad is formed by the section of the redistribution layer.

2. The wafer arrangement of claim 1, wherein each first connection is assigned a second connection arranged on a section of a redistribution layer, wherein the second connections are coupled by means of a section of a redistribution layer.

3. The wafer arrangement of claim 2, wherein the section that has the second connection and the section that couples the second connections to one another are sections of the same redistribution layer.

4. The wafer arrangement of claim 2, wherein the section that has the second connection and the section that couples the second connections to one another are sections of two separate redistribution layers, wherein the contact pad is formed by one of the redistribution layers.

5. The wafer arrangement of claim 2, wherein the plurality of dice in each case has a plurality of first connections and a plurality of second connections and at least some of the respectively mutually corresponding second connections of at least some of the dice are coupled by means of a respective section of the same redistribution layer, a contact pad in each case being formed at the section.

6. The wafer arrangement of claim 5, wherein at least some of the respectively mutually corresponding first connections or of the mutually corresponding second connections of at least some of the dice arranged alongside one another in a row are coupled by means of a respective section of the same redistribution layer.

7. The wafer arrangement of claim 1, wherein at least one further first connection of each of the plurality of dice is coupled to a separate section of a redistribution layer, a contact pad being formed by the separate section.

8. The wafer arrangement of claim 2, wherein at least one further second connection of each of the plurality of dice is coupled to a separate section of a redistribution layer, a contact pad being formed by the separate section.

9. The wafer arrangement of claim 8, wherein the at least one further second connection is a chip select connection.

10. The wafer arrangement of claim 1, wherein at least that section of the redistribution layer by which the respective connections are coupled to one another is arranged at least section by section in singulation regions between the dice.

11. The wafer arrangement of claim 1, wherein at least that section of the redistribution layer by which the respective connections are coupled to one another and by which a contact pad is formed is arranged at least section by section on free areas on the dice.

12. The wafer arrangement of claim 1, which is set up for carrying out burn-in and test methods of dice at a wafer level.

13. The wafer arrangement of claim 1, wherein the contact pads formed by a section of the redistribution layer are set up for contact-connection to connections of a burn-in and test contact-connecting apparatus.

14. The wafer arrangement of claim 1, wherein the contact pads formed by a section of the redistribution layer in each case have a pad contact-connection element.

15. The wafer arrangement of claim 1, wherein the dice comprise memory chips.

16. The wafer arrangement of claim 1, wherein the dice comprise logic chips.

17. A method for manufacturing a wafer arrangement, the method comprising:
forming a plurality of dice in a wafer, such that at least some of the dice have a first connection; and
forming a redistribution layer in such a way that a plurality of first connections of at least some of the dice are coupled to one another and a section of a redistribution layer is arranged in an edge region of the wafer and formed as a contact pad.

18. The method of claim 17, wherein, for each first connection, a second connection is formed that is arranged on a section of a redistribution layer that is coupled to a first connection, wherein the second connections of the dice are coupled by means of a section of a redistribution layer at which the contact pad is formed.

19. The method of claim 18, wherein the section that forms the second connection and the section that couples the second connections to one another are formed by means of the same redistribution layer.

20. The method of claim 18, wherein the section that forms the second connection and the section that couples the second connections to one another are formed by means of separate redistribution layers.

21. The method of claim 18, wherein each die in the plurality of dice has a plurality of first connections or of second connections, wherein forming the redistribution layer is effected in such a way that at least some of the respectively mutually corresponding connections of at least some of the dice are coupled to one another by means of a respective section of the redistribution layer, the section being formed right into an edge region of the wafer.

22. The method of claim 18, further comprising:
forming a redistribution layer while producing sections for coupling of mutually corresponding second connections; and
forming a further redistribution layer while producing the second connections and coupling sections which have mutually corresponding second connections to a respective assigned section of those sections of the redistribution layer which extend right into the edge region of the wafer.

23. The method of claim 17, further comprising:
forming the redistribution layer while producing separate sections which are in each case coupled to a further first connection of each of the plurality of dice and are formed right into the edge region of the wafer for the purpose of providing a contact pad.

24. The method of claim 18, further comprising:
forming the redistribution layer while producing separate sections which are in each case coupled to a further second connection of each of the plurality of dice and are formed right into the edge region of the wafer for the purpose of providing a contact pad.

25. The method of claim 17, further comprising performing a burn-in and test method to test ones of the dice, wherein at least sections of the redistribution layer that couple the connections to one another are removed after the burn-in and test method during singulation of the wafers.

26. The method of claim 17, wherein at least sections of the redistribution layer that couple the connections to one another are removed after the burn-in and test method by means of laser cutting of the wafer.

27. The method of claim 17, wherein at least sections of the redistribution layer that couple the connections to one another are removed after the burn-in and test method by means of sawing of the wafer.

28. The method of claim 17, wherein at least sections of the redistribution layer are removed after the burn-in and test method by means of an etching process.

29. An apparatus for carrying out a burn-in and test process of wafer having a plurality of dice and a contact pad formed at an edge of the wafer, wherein at least some of the dice have a first connection and, wherein a plurality of first connections are coupled by means of a section of a redistribution layer, and wherein the contact pad is formed by the section of the redistribution layer, the apparatus comprising:
a contact-connecting apparatus having contact connections that are formed for making electrical contact with contact pads on the wafer;
wherein all dice coupled to the contact-connected contact pads can be simultaneously subjected to a predefinable burn-in and test process by means of the contact-connecting apparatus.

30. The apparatus of claim 29, wherein the contact-connecting apparatus is part of a burn-in device.

31. A method for a burn-in and test process of dice on a wafer, the method comprising:
providing a wafer having a plurality of dice, and a contact pad formed at an edge of the wafer, wherein at least some of the dice have a first connection, wherein a plurality of first connections are coupled by means of a section of a redistribution layer, and wherein the contact pad is formed by the section of the redistribution layer;
contact-connecting the contact pads arranged on the wafer by means of a contact-connecting apparatus in a burn-in and test device;
loading all the dice coupled to the contact pads under predetermined burn-in parameters; and
testing the dice at defined time intervals during and after the burn-in treatment.
